(19) United States
(12) Patent Application Publication
(10) Pub. No.: US 2024/0071850 A1
(43) Pub. Date: Feb. 29, 2024

(54) SEMICONDUCTOR STRUCTURE WITH HYBRID FILM AND METHOD OF MANUFACTURING THE SAME

(71) Applicant: TAIWAN SEMICONDUCTOR MANUFACTURING COMPANY LTD., HSINCHU (TW)

(72) Inventors: FU-MING HSU, NEW TAIPEI CITY (TW); MING-JIE HUANG, HSINCHU CITY (TW); ZHEN-CHENG WU, HSINCHU (TW); YUNG-CHENG LU, HSINCHU CITY (TW)

(21) Appl. No.: 17/822,808

(22) Filed: Aug. 29, 2022

(51) Int. Cl. H01L 23/29; H01L 21/02; H01L 21/3065; H01L 23/31; H01L 23/532

(52) U.S. Cl. CPC H01L 23/291; H01L 21/02274; H01L 21/3065; H01L 23/3135; H01L 23/5329

(57) ABSTRACT

The present disclosure provides a semiconductor structure and a method of manufacturing a semiconductor structure. The semiconductor structure includes a substrate, semiconductor structures, an isolation layer, an adhesive layer, a metal layer, a metal nitride layer, a semiconductor layer, a profile modifier layer, and a disconnection structure. The semiconductor structures are disposed on the substrate. The isolation layer is disposed between the semiconductor structures. The metal layer is disposed on an adhesive layer. The metal nitride layer is disposed on the metal layer. The semiconductor layer is disposed on the metal nitride layer. The profile modifier layer is disposed on the semiconductor layer. The disconnection structure is disposed and extending from the profile modifier layer to the isolation layer. A first width of the disconnection structure in the profile modifier layer is substantially the same as a second width of the disconnection structure in the isolation layer.

### BACKGROUND

The present invention relates generally to semiconductor structures, and more particularly to semiconductor structures with a hybrid film and methods of manufacturing the same.

Nanosheets are recognized as promising candidates to replace finfet structures. However, traditional hard mask pattern materials suffer from top corner profile rounding and high thermal budge in film deposition process. Solutions have been developed to address such issues.

### BRIEF DESCRIPTION OF THE DRAWINGS

Aspects of the embodiments of the present disclosure are best understood from the following detailed description when read with the accompanying figures. It should be noted that, in accordance with the standard practice in the industry, various structures are not drawn to scale. In fact, the dimensions of the various structures may be arbitrarily increased or reduced for clarity of discussion.

FIG. 1 illustrates an exemplary cross-section of a semiconductor structure, in accordance with some embodiments of the present disclosure.

FIG. 2 illustrates an exemplary cross-section of a semiconductor structure, in accordance with some embodiments of the present disclosure.

FIG. 3A, FIG. 3B, FIG. 3C, FIG. 3D, FIG. 3E, FIG. 3F, FIG. 3G, FIG. 3H, FIG. 3I, FIG. 3J, FIG. 3K, FIG. 3L, FIG. 3M, and FIG. 3N illustrate various stages of manufacturing a semiconductor device structure, in accordance with some embodiments of the present disclosure.

FIG. 3A, FIG. 3B, FIG. 3C, FIG. 3D, FIG. 3E, FIG. 3F, FIG. 3G, FIG. 3H, FIG. 4A, FIG. 4B, FIG. 4C, FIG. 4D, and FIG. 4E illustrate various stages of manufacturing a semiconductor device structure, in accordance with some embodiments of the present disclosure.

FIG. 5 illustrates an exemplary cross-section of a semiconductor structure, in accordance with some comparative embodiments of the present disclosure.

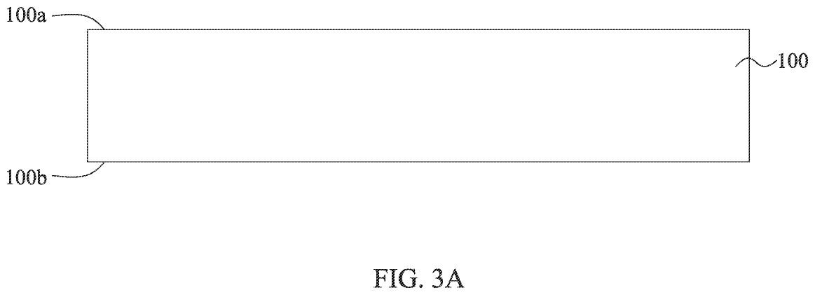

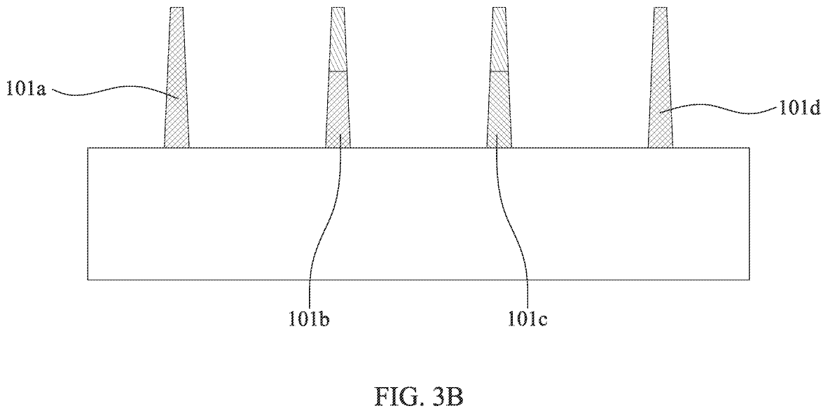

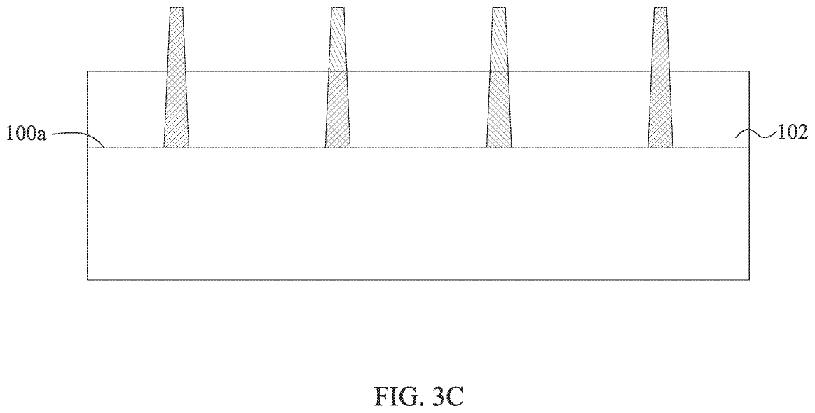

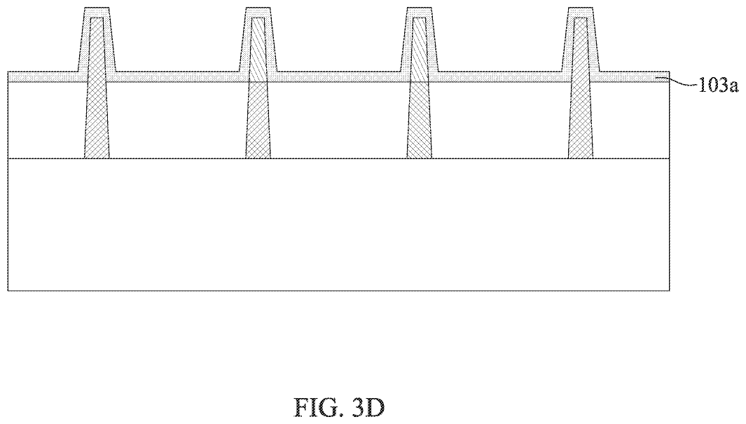

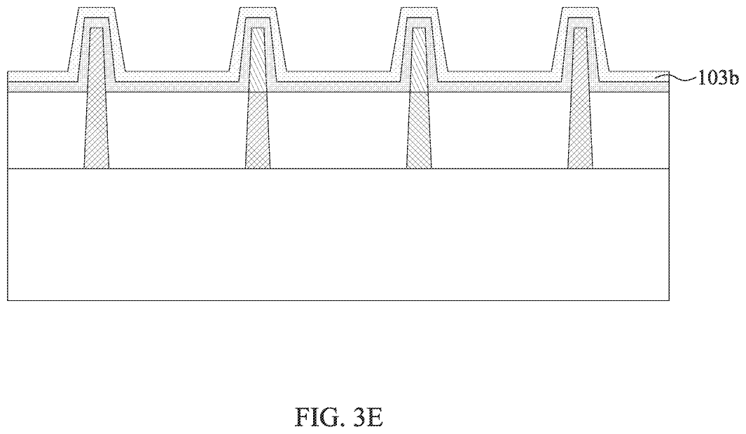

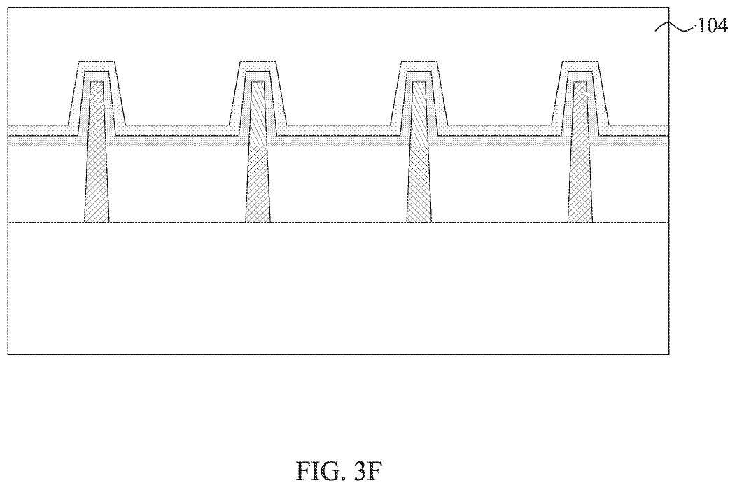

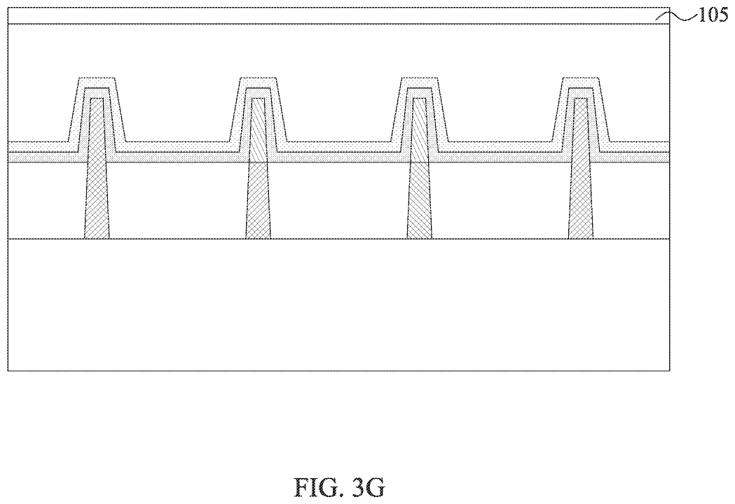

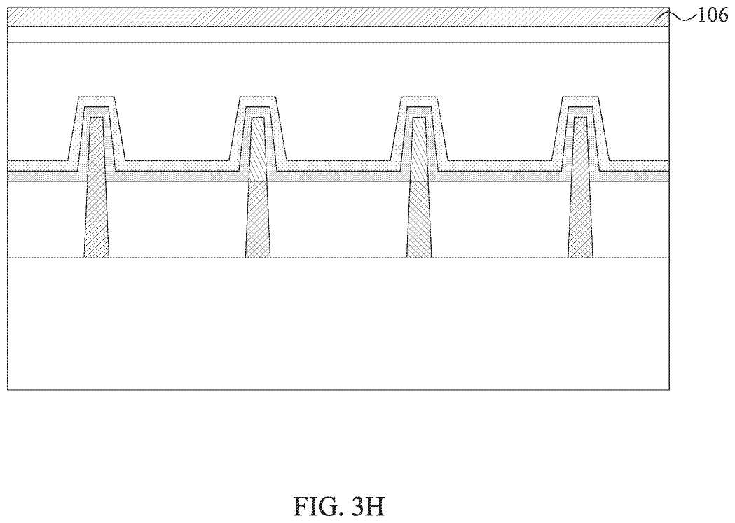

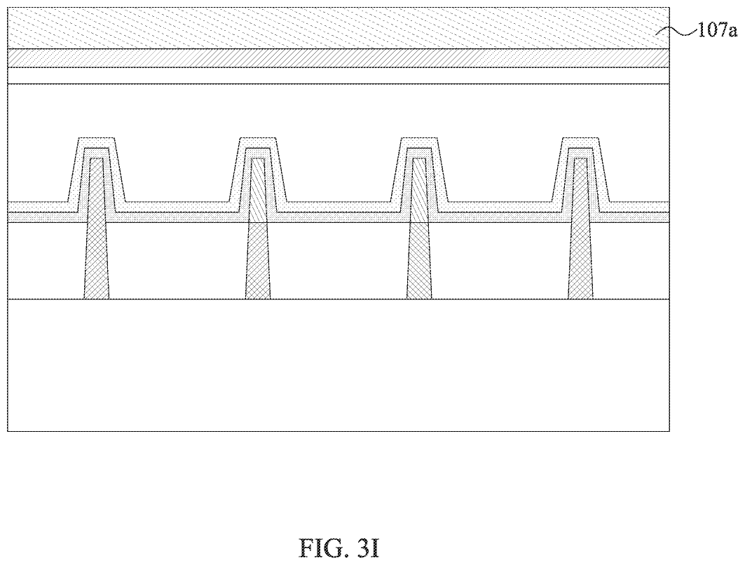

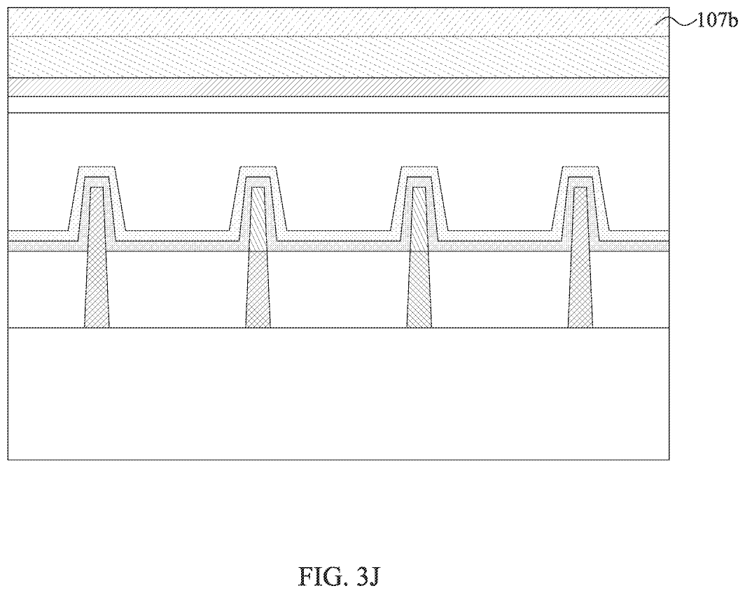

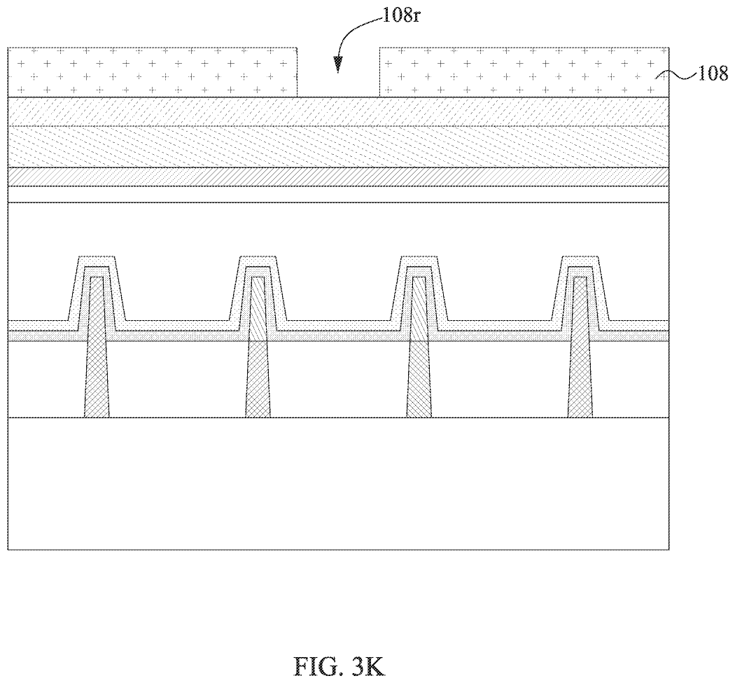

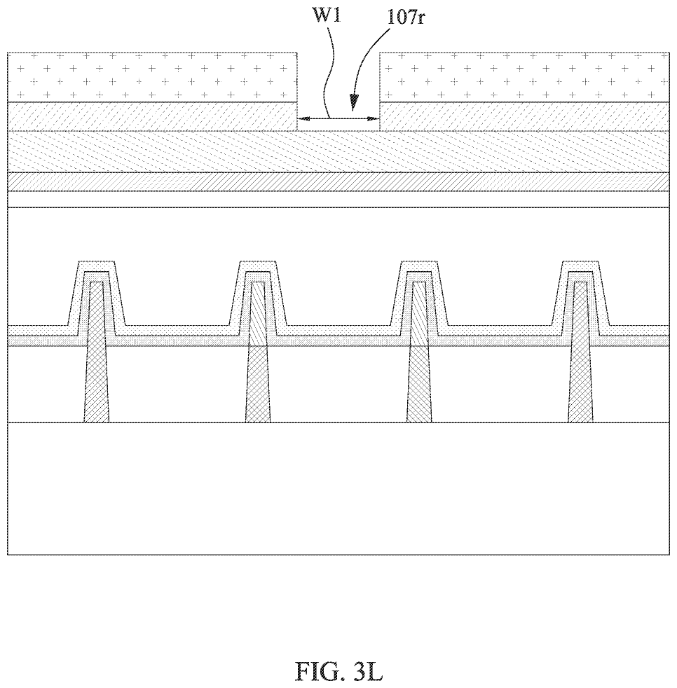

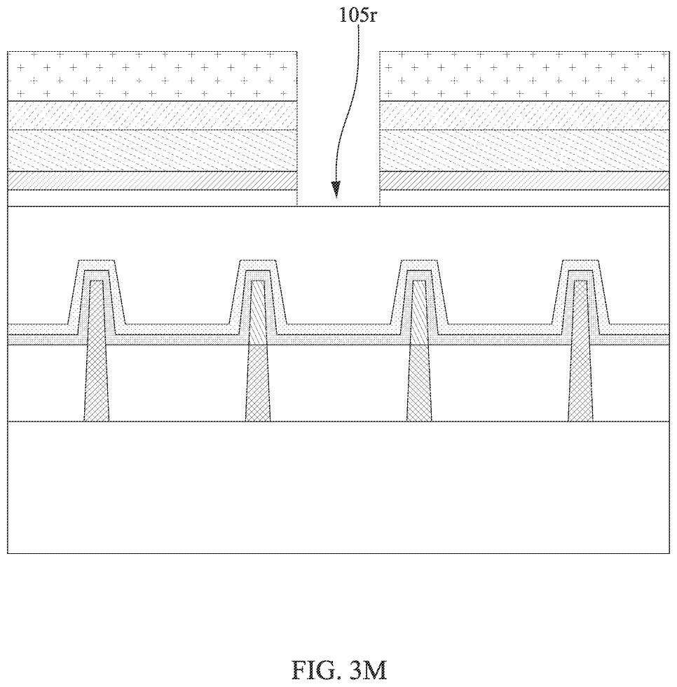

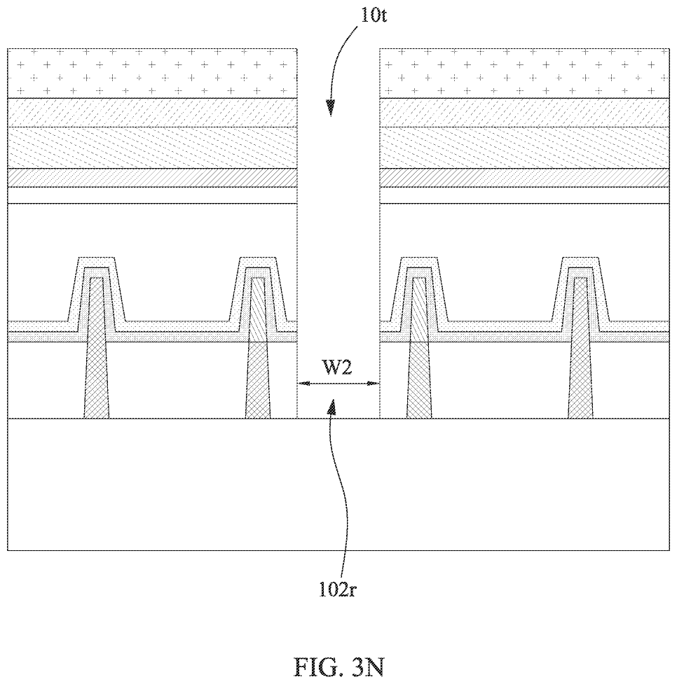

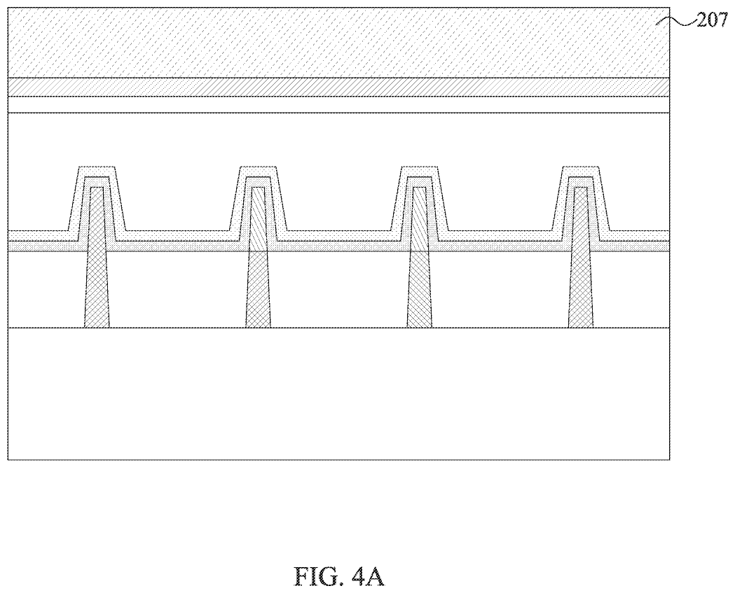

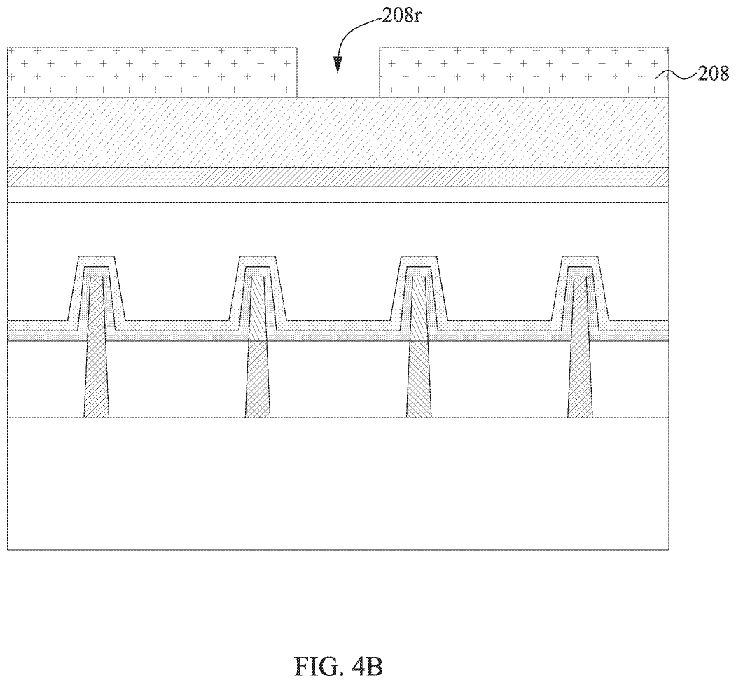

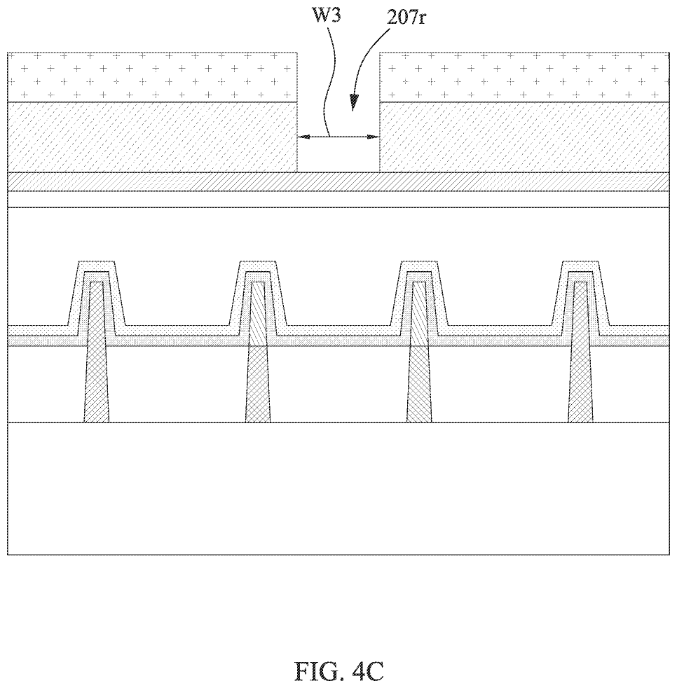

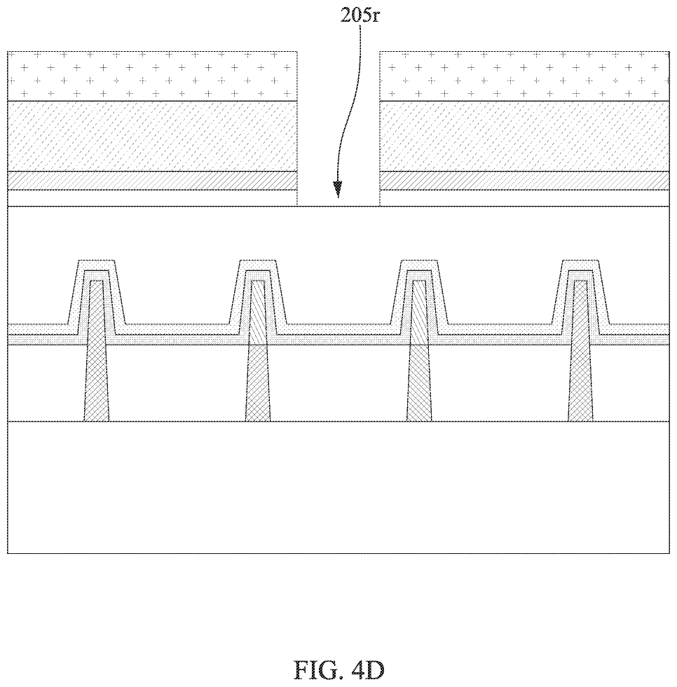

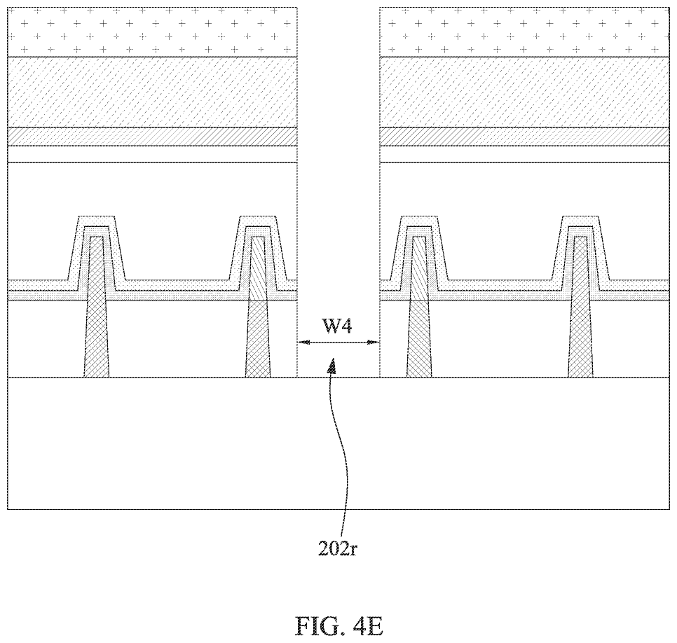

FIG. 3A, FIG. 3B, FIG. 3C, FIG. 3D, FIG. 3E, FIG. 3F, FIG. 3G, FIG. 3H, FIG. 6A, FIG. 6B, FIG. 6C, FIG. 6D, and FIG. 6E illustrate various stages of manufacturing a semiconductor device structure, in accordance with some embodiments of the present disclosure.

FIG. 7 is a flowchart illustrating a method for manufacturing a semiconductor structure, in accordance with various aspects of the present disclosure.

FIGS. 8A and 8B are flowcharts illustrating a method for manufacturing a semiconductor structure, in accordance with various aspects of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, although terms such as “first,” “second” and “third” describe various elements, components, regions, layers and/or sections, these elements, components, regions, layers and/or sections should not be limited by these terms. These terms may only be used to distinguish one element, component, region, layer or section from another. Terms such as “first,” “second” and “third” when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the terms “substantially,” “approximately” and “about” generally mean within a value or range that can be contemplated by people having ordinary skill in the art. Alternatively, the terms “substantially,” “approximately” and “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

A hybrid film is proposed as a hard mask pattern material to address both issues of top corner profile rounding and high thermal budge of film deposition process.

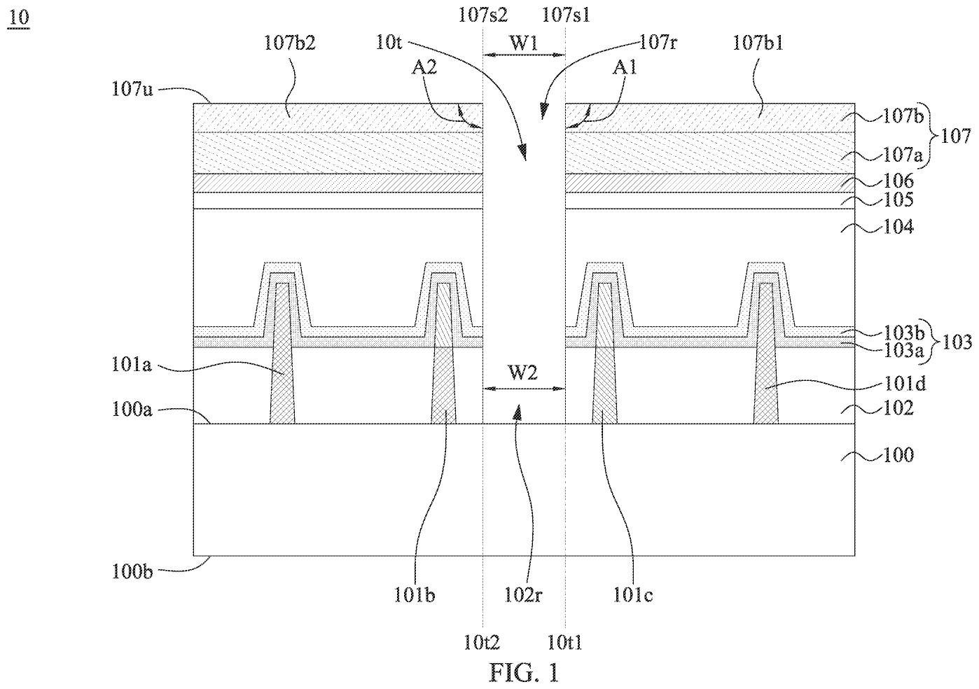

FIG. 1 illustrates an exemplary cross-section of a semiconductor structure 10, in accordance with some embodiments of the present disclosure. The semiconductor structure 10 includes a substrate 100. The substrate 100 has a surface 100a and a surface 100b opposite to the surface 100a. Semiconductor structures 101a-101d are formed on the surface 100a of the substrate 100. In some embodiments, the doping type of the semiconductor structures 101a and 101d may be different from that of the semiconductor structures 101b and 101c. The semiconductor structures 101a-101d are spaced apart from each other. In some embodiments, the semiconductor structures 101a-101d includes nanostructures.

An isolation layer 102 is disposed on the surface 100a of the substrate 100. The isolation layer 102 contacts the semiconductor structures 101a-101d. The isolation layer 102 surrounds the semiconductor structures 101a-101d. The isolation layer 102 contacts the substrate 100. The isolation layer 102 fills the gaps between the semiconductor structures 101a-101d. In some embodiments, the thickness of the isolation layer 102 may be in a range of about 100 Å to about 5000 Å. The thickness of the isolation layer 102 is less than the height of the semiconductor structures 101a-101d. The isolation layer 102 separates the semiconductor structures 101a-101d. In some embodiments, the isolation layer 102 includes a dielectric material. In some embodiments, the isolation layer 102 includes a silicon oxide layer.

An adhesive layer 103 is disposed on the isolation layer 102. The adhesive layer 103 may include two layers 103a and 103b. The layers 103a and 103b may include different materials. The layer 103a is disposed on the semiconductor structures 101a-101d and the isolation layer 102. The layer 103a can be conformally disposed on the semiconductor structures 101a-101d and the isolation layer 102. The layer 103a contacts the semiconductor structures 101a-101d and the isolation layer 102. The layer 103b is disposed on the layer 103a. The layer 103b contacts the layer 103a. In some embodiments, the layer 103b may include a conductive layer. In some embodiments, the thickness of the layer 103a is in a range of about 5 Å to about 200 Å. In some embodiments, the thickness of the layer 103b is in a range of about 5 Å to about 200 Å.

In some embodiments, the layer 103a may include one or more high-k dielectric materials (or one or more layers of high-k dielectric materials), such as hafnium silicon oxide (HfSiO), hafnium oxide (HfO₂), alumina (Al₂O₃), zirconium oxide (ZrO₂), lanthanum oxide (La₂O₃), titanium oxide (TiO₂), yttrium oxide (Y₂O₃), strontium titanate (SrTiO₃), or a combination thereof.

In some embodiments, the layer 103b may include one or more metal layers, such as work function metal layers, conductive barrier layers, and metal fill layers. The work function metal layer may be a p-type or an n-type work function layer depending on the type (PFET or NFET) of the device. The p-type work function layer comprises a metal selected from, but not restricted to, the group of titanium nitride (TiN), tantalum nitride (TaN), ruthenium (Ru), molybdenum (Mo), tungsten (W), platinum (Pt), or combinations thereof. The n-type work function layer comprises metal selected from, but not restricted to, the group of titanium (Ti), aluminum (Al), tantalum carbide (TaC), tantalum carbide nitride (TaCN), tantalum silicon nitride (TaSiN), titanium silicon nitride (TiSiN), or combinations thereof. The metal fill layer may include aluminum (Al), tungsten (W), cobalt (Co), and/or other suitable materials.

A metal layer 104 is disposed on the layer 103b of the adhesive layer 103. The metal layer 104 contacts the layer 103b of the adhesive layer 103. The adhesive layer 103 adheres the metal layer 104 to the semiconductor structures 101a-101d and the isolation layer 102. In some embodiments, the thickness of the metal layer 104 is in a range of about 100 Å to about 5000 Å. In some embodiments, the thickness of the metal layer 104 exceeds that of the adhesive layer 103.

A metal nitride layer 105 is disposed on the metal layer 104. The metal nitride layer 105 contacts the metal layer 104. In some embodiments, the metal nitride layer 105 includes a silicon nitride layer. In some embodiments, the thickness of the metal nitride layer 105 is in a range of about 10 Å to about 500 Å. In some embodiments, the thickness of the metal nitride layer 105 is less than that of the metal layer 104.

A semiconductor layer 106 is disposed on the metal nitride layer 105. The semiconductor layer 106 contacts the metal nitride layer 105. In some embodiments, the semiconductor layer 106 includes a silicon layer. In some embodiments, the thickness of the semiconductor layer 106 is in a range of about 10 Å to about 500 Å.

A profile modifier layer 107 is disposed on the semiconductor layer 106. In some embodiments, the profile modifier layer 107 is a hybrid film. A hybrid film can also be referred to as a composite film. In some embodiments, the profile modifier layer 107 includes two protection layers 107a and 107b. The protection layer 107a is disposed on the semiconductor layer 106. The protection layer 107a contacts the semiconductor layer 106. The protection layer 107b is disposed on the protection layer 107a. The protection layer 107b contacts the protection layer 107a. In some embodiments, the thickness of the protection layer 107a is in a range of about 10 Å to about 500 Å. In some embodiments, the thickness of the protection layer 107b is in a range of about 10 Å to about 500 Å. In some embodiments, the thickness of the protection layer 107a exceeds that of the protection layer 107b.

As shown in FIG. 1, a recess 10t is disposed between and separates the semiconductor structures 101b and 101c. The recess 10t extends from a top surface 107u of the profile modifier layer 107 to the surface 100a of the substrate 100. The recess 10t extends from the profile modifier layer 107 to the isolation layer 102. The isolation layer 102, the adhesive layer 103, the metal layer 104, the metal nitride layer 105, the semiconductor layer 106, and the profile modifier layer 107 are separated into two sections by the recess 10t. In some embodiments, the recess 10t is substantially rectangular. In some embodiments, the depth of the recess 10t is in a range of about 250 Å to about 12400 Å.

The recess 10t may include openings for separating the isolation layer 102, the adhesive layer 103, the metal layer 104, the first metal nitride layer 105, the semiconductor layer 106, and the profile modifier layer 107. In some embodiments, an opening 102r separates the isolation layer 102 into two sections. An opening 107r separates the profile modifier layer 107 into two sections. A width W1 of the opening 107r in the profile modifier layer 107 is substantially the same as a width W2 of the opening 102r in the isolation layer 102. The recess 10t separates the profile modifier layer 107 by the width W1 and separates the isolation layer 102 by the width W2 substantially identical to the width W1. In some embodiments, one side surface 10t of the recess 10t is substantially parallel to another side surface 10t2 of the recess 10t.

As shown in FIG. 1, an angle A1 between a surface 107u and a side surface 107s1 of a section 107b1 of the protection layer 107b of the profile modifier layer 107 is a substantially right angle. In some embodiments, the angle A1 exceeds 80°. In some embodiments, the angle A1 is less than 100°. An angle A2 between the surface 107u and a side surface 107s2 of a section 107b2 of the protection layer 107b of the profile modifier layer 107 is a substantially right angle. In some embodiments, the angle A2 exceeds 80°. In some embodiments, the angle A2 is less than 100°. In some embodiments, the angle A1 exceeds the angle A2. In some embodiments, the angle A1 is less than the angle A2. In some embodiments, the angle A1 is substantially the same as the angle A2.

In some embodiments, the protection layer 107b may protect the protection layer 107a from damage during the CMG process. The protection layer 107b may prevent the protection layer 107a from experiencing top corner profile rounding during the CMG process. In some embodiments, the protection layer 107b has a greater etching resistivity to CMG process than that of the protection layer 107a. In some embodiments, the protection layer 107b may protect the semiconductor layer 106 from damage during the CMG process. In some embodiments, the protection layer 107b may protect the metal nitride layer 105 from damage during the CMG process. In some embodiments, the protection layer 107b may protect the metal layer 104 from damage during the CMG process.

In some embodiments, the protection layer 107a comprises one of SiCN, SiN, SiCON, SiOC, or SiON. In some embodiments, the protection layer 107b comprises a metal oxide layer or a metal nitride layer. In some embodiments, the metal material of the metal oxide layer or the metal nitride layer of the protection layer 107b is selected from Zr, Hf, Al, or Y.

In some embodiments, a disconnection structure (not shown) can be disposed in the recess 10t. The disconnection structure can be disposed between the semiconductor structures 101b and 101c and extends from the profile modifier layer 107 to the isolation layer 102. In some embodiments, the disconnection structure disposed in the recess 10t can be a spacer. The spacer may comprise a dielectric material, such as silicon oxide, silicon nitride, silicon oxynitride, silicon carbide, other dielectric material, or combinations thereof. The disconnection structure separates the isolation layer 102, the adhesive layer 103, the metal layer 104, the first metal nitride layer 105, the semiconductor layer 106, and the profile modifier layer 107. In some embodiments, a width of the disconnection structure in the profile modifier layer 107 is substantially the same as the width W1 of the opening 107r in the profile modifier layer 107. In some embodiments, a width of the disconnection structure in the isolation layer 102 is substantially the same as the width W2 of the opening 102r in the isolation layer 102. In some embodiments, the width of the disconnection structure in the profile modifier layer 107 is substantially the same as the width of the disconnection structure in the isolation layer 102.

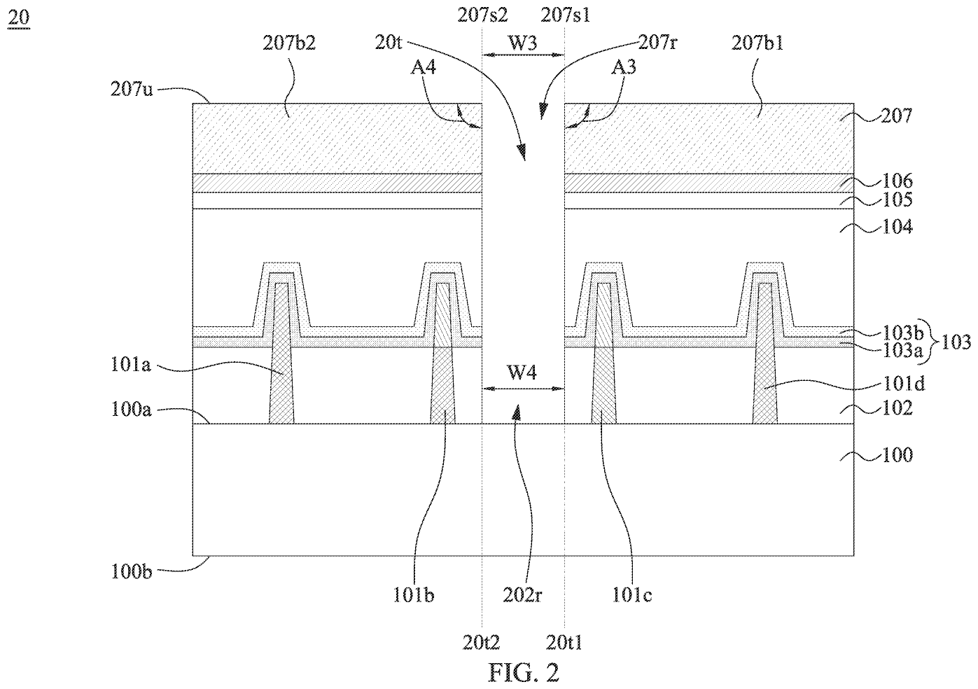

FIG. 2 illustrates an exemplary cross-section of a semiconductor structure 20, in accordance with some embodiments of the present disclosure. The difference between FIG. 1 and FIG. 2 includes the protection layer 107 shown in FIG. 1 being replaced by a protection layer 207. The protection layer 207 is formed on the semiconductor layer 106. In some embodiments, the protection layer 207 contacts the semiconductor layer 106. In some embodiments, the thickness of the protection layer 207 is in a range of about 20 Å to about 1000 Å. In some embodiments, the thickness of the protection layer 207 exceeds that of the semiconductor layer 106.

In some embodiments, the protection layer 207 comprises a metal oxide layer or a metal nitride layer. In some embodiments, the metal material of the metal oxide layer or the metal nitride layer of the protection layer 207 is selected from Zr, Hf, Al, or Y.

The protection layer 207 may prevent the semiconductor layer 106 from experiencing top profile corner rounding during the CMG process. In some embodiments, the protection layer 207 has a greater etching resistivity to CMG process than that of the semiconductor layer 106. In some embodiments, the protection layer 207 may protect the semiconductor layer 106 from damage during the CMG process. In some embodiments, the protection layer 207 may protect the metal nitride layer 105 from damage during the CMG process. In some embodiments, the protection layer 207 may protect the metal layer 104 from damage during the CMG process. The protection layer 207 can also be referred to as a profile modifier layer in the present disclosure.

As shown in FIG. 2, a recess 20t is disposed between the semiconductor structures 101b and 101c. The recess 20t separates the semiconductor structures 101b and 101c. The recess 20t extends from a top surface 207u of the protection layer 207 to the surface 100a of the substrate 100. The recess 20t extends from the protection layer 207 to the isolation layer 102. The isolation layer 102, the adhesive layer 103, the metal layer 104, the metal nitride layer 105, the semiconductor layer 106, and the profile modifier layer 107 are separated by the recess 20t into two sections. In some embodiments, the recess 20t is substantially rectangular in cross section. In some embodiments, the depth of the recess 20t is in a range of about 250 Å to about 12400 Å.

The recess 20t may include openings for separating the isolation layer 102, the adhesive layer 103, the metal layer 104, the first metal nitride layer 105, the semiconductor layer 106, and the protection layer 207. In some embodiments, an opening 202r separates the isolation layer 102 into two sections. An opening 207r separates the protection layer 207 into two sections. A width W3 of the opening 207r in the protection layer 207 is substantially the same as a width W4 of the opening 202r in the isolation layer 102. The recess 20t separates the protection layer 207 by the width W3 and separates the isolation layer 102 by the width W4 substantially identical to the width W3. In some embodiments, one side surface 20t1 of the recess 20t is substantially parallel to another side surface 20t2 of the recess 20t.

As shown in FIG. 2, an angle A3 between a surface 207u and a side surface 207s1 of a section 207b1 of the protection layer 207 is a substantially right angle. In some embodiments, the angle A3 exceeds 80°. In some embodiments, the angle A3 is less than 100°. An angle A4 between the surface 207u and a side surface 207s2 of a section 207b2 of the protection layer 207 is a substantially right angle. In some embodiments, the angle A4 exceeds 80°. In some embodiments, the angle A4 is less than 100°. In some embodiments, the angle A3 exceeds the angle A4. In some embodiments, the angle A3 is less than the angle A4. In some embodiments, the angle A3 is substantially the same as the angle A4. In some embodiments, the side surface 207s1 of the opening 207r is substantially parallel to the side surface 207s2 of the opening 207r.

FIG. 3A, FIG. 3B, FIG. 3C, FIG. 3D, FIG. 3E, FIG. 3F, FIG. 3G, FIG. 3H, FIG. 3I, FIG. 3J, FIG. 3K, FIG. 3L, FIG. 3M, and FIG. 3N illustrate various stages of manufacturing a semiconductor device structure, in accordance with some embodiments of the present disclosure.

As shown in FIG. 3A, a substrate 100 is provided. The substrate 100 has a surface 100a and a surface 100b opposite the surface 100a.

Referring to FIG. 3B, semiconductor structures 101a, 101b, 101c, and 101d are formed on the surface 100a of the substrate 100. The semiconductor structures 101a, 101b, 101c, and 101d are spaced apart from each other. In some embodiments, the doping type of the semiconductor structures 101a and 101d may be different from that of the semiconductor structures 101b and 101c. In some embodiments, the distance between the semiconductor structures 101a and 101b, the distance between the semiconductor structures 101b and 101c, and the distance between the semiconductor structures 101c and 101d are substantially the same.

As shown in FIG. 3C, an isolation layer 102 is formed on the surface 100a of the substrate 100. The isolation layer 102 fills in the space between the semiconductor structures 101a and 101b, the space between the semiconductor structures 101b and 101c, and the space between the semiconductor structures 101c and 101d. In some embodiments, the isolation layer 102 is formed as shallow trench isolations (STI). In some embodiments, the isolation layer 102 is formed by chemical vapor deposition (CVD). In some embodiments, the isolation layer 102 is formed with oxide materials.

Referring to FIG. 3D, a layer 103a is formed on the semiconductor structures 101a, 101b, 101c, and 101d and the isolation layer 102. In some embodiments, the layer 103a may include a high-k material. The layer 103a contacts the semiconductor structures 101a, 101b, 101c, and 101d and the isolation layer 102.

Referring to FIG. 3E, a layer 103b is formed on the layer 103a. In some embodiments, the layer 103b may include a conductive material. The layer 103b contacts the layer 103a. The layers 103a and 103b form an adhesive layer 103. In some embodiments, the material of the layer 103a may be different from that of the layer 103b. In some embodiments, the thickness of the layer 103b is different from that of the layer 103a. In some embodiments, the thickness of the layer 103b exceeds that of the layer 103a.

As shown in FIG. 3F, a metal layer 104 is formed on the layer 103b. The metal layer 104 contacts the layer 103b. In some embodiments, the thickness of the metal layer 104 exceeds that of the adhesive layer 103. The metal layer 104 is separated from the isolation structure 102 by the adhesive layer 103. In some embodiments, the metal layer 104 is connected to the semiconductor structures 101a, 101b, 101c, and 101d and the isolation layer 102 by the adhesive layer 103.

Referring to FIG. 3G, a metal nitride layer 105 is formed on the metal layer 104. The metal nitride layer 105 contacts the metal layer 104. In some embodiments, the thickness of the metal nitride layer 105 is less than that of the metal layer 104.

As shown in FIG. 3H, a semiconductor layer 106 is formed on the metal nitride layer 105. The semiconductor layer 106 contacts the metal nitride layer 105.

Referring to FIG. 3I, a protection layer 107a is formed on the semiconductor layer 106. The protection layer 107a contacts the semiconductor layer 106. In some embodiments, the protection layer 107a may include a dielectric material. In some embodiments, the protection layer 107a may include silicon nitride. In some embodiments, the protection layer 107a may be formed by plasma enhanced chemical vapor deposition (PECVD). In some embodiments, the thickness of the protection layer 107a exceeds that of the semiconductor layer 106.

Referring to FIG. 3J, a protection layer 107b is formed on the protection layer 107a. The protection layer 107b contacts the protection layer 107a. In some embodiments, the protection layer 107b may be formed by plasma enhanced chemical vapor deposition (PECVD). In some embodiments, the thickness of the protection layer 107a exceeds that of the protection layer 107b.

As shown in FIG. 3K, a patterned photoresist layer 108 is formed on the protection layer 107b. The patterned photoresist layer 108 contacts the protection layer 107b. The patterned photoresist layer 108 includes two separated sections. The two sections are spaced apart by an opening 108r. In some embodiments, the opening 108r is substantially disposed in the center of the patterned photoresist layer 108. In some embodiments, the opening 108r is formed between the semiconductor structures 101b and 101c in a vertical orientation.

Referring to FIG. 3L, the protection layer 107b is patterned. An opening 107r is formed. In some embodiments, the opening 107r is formed by patterning the protection layer 107b of the profile modifier layer 107 by lithography. The protection layer 107b is separated into two sections. Two side surfaces of the opening 107r are substantially aligned with two side surfaces of the opening 108r. In some embodiments, the opening 107r is formed by dry etching. The opening 107r has a width W1.

Referring to FIG. 3M, the metal nitride layer 105, the semiconductor layer 106, and the protection layer 107a are patterned. An opening 105r is formed. Two side surfaces of the opening 105r are substantially aligned with two side surfaces of the opening 108r. In some embodiments, the opening 105r is formed by dry etching. In some embodiments, the opening 105r is formed by patterning the metal nitride layer 105 by lithography.

After the metal nitride layer 105, the semiconductor layer 106, and the profile modifier 107 are patterned, a cut metal gate (CMG) process is performed. The CMG process refers to a fabrication process where after a metal gate (e.g., a high-k metal gate) replaces a dummy gate structure (e.g., a polysilicon gate), the metal gate is cut (e.g., by an etching process) to separate the metal gate into two or more portions. Each portion functions as a metal gate for an individual transistor.

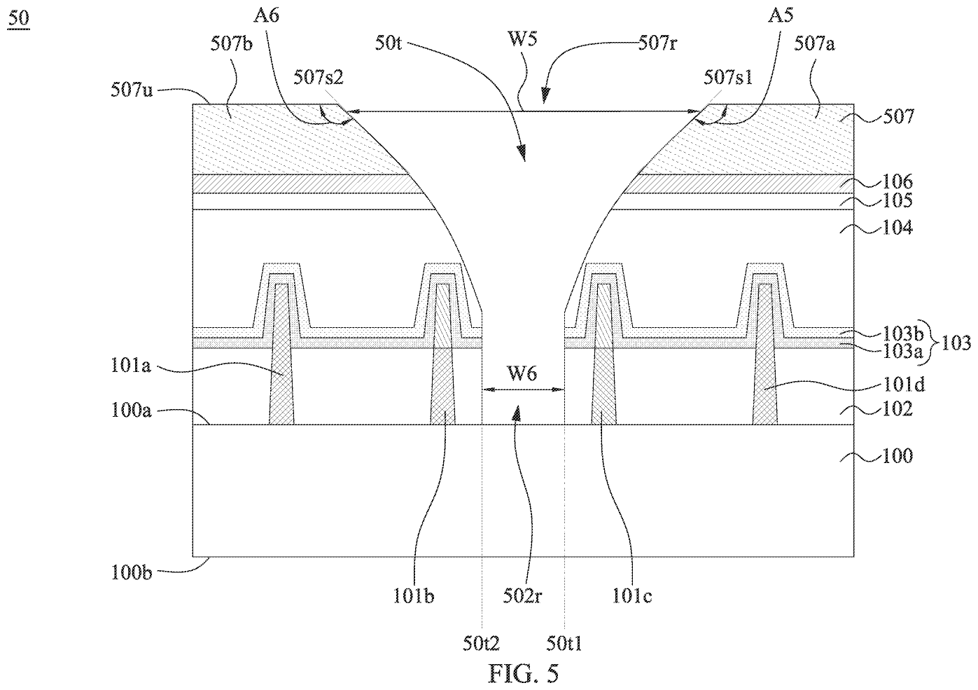

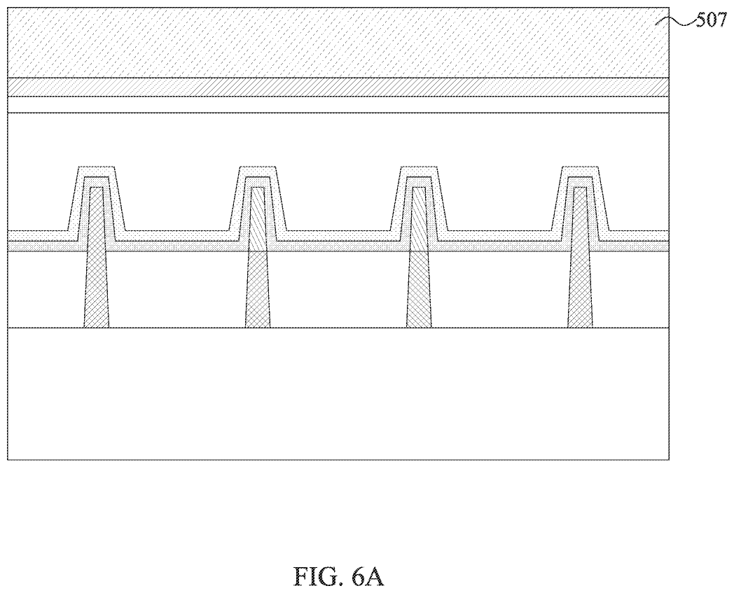

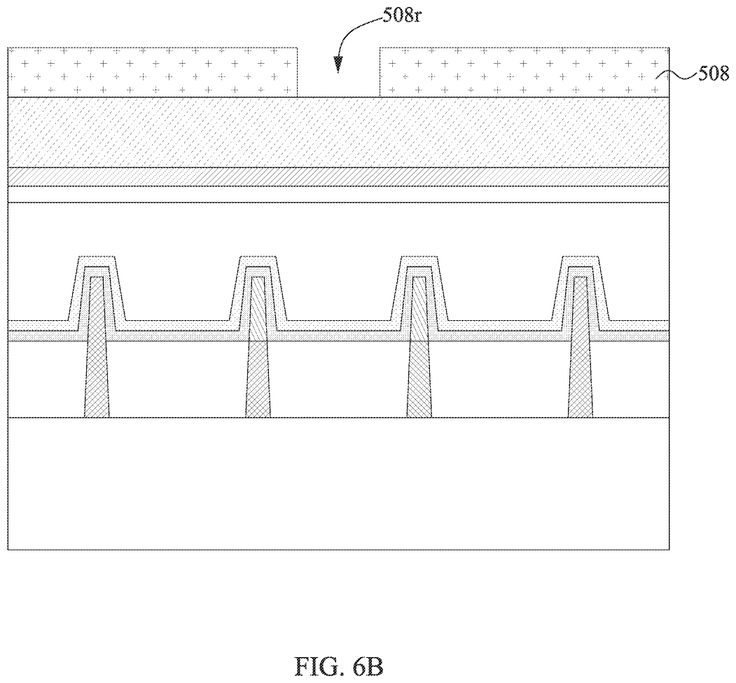

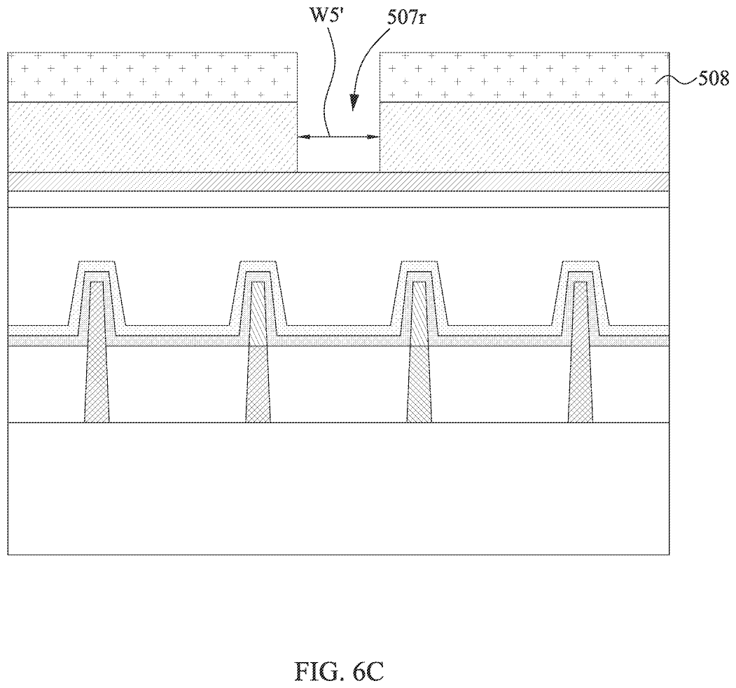

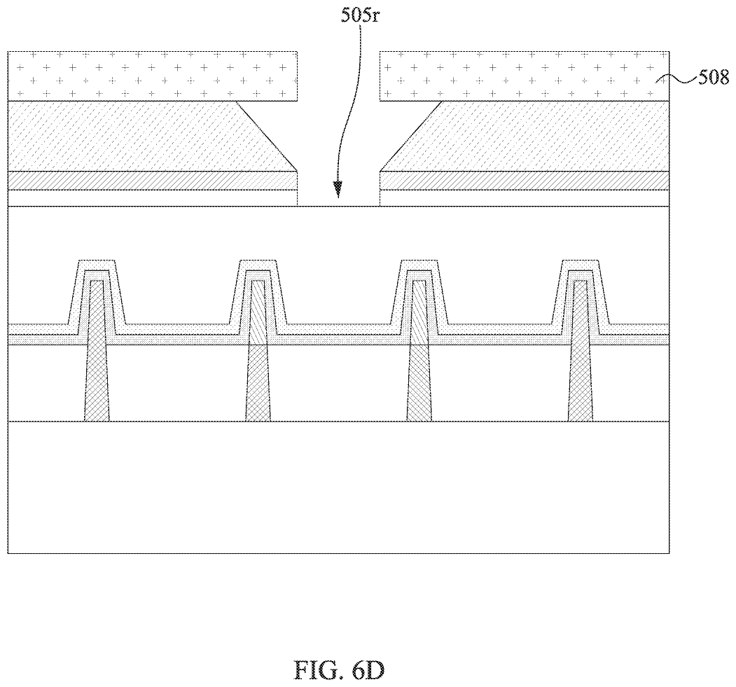

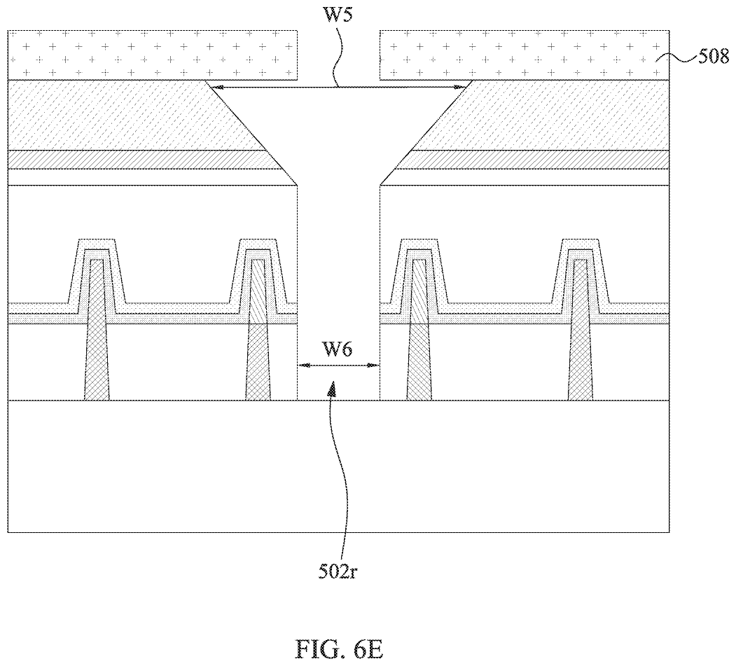

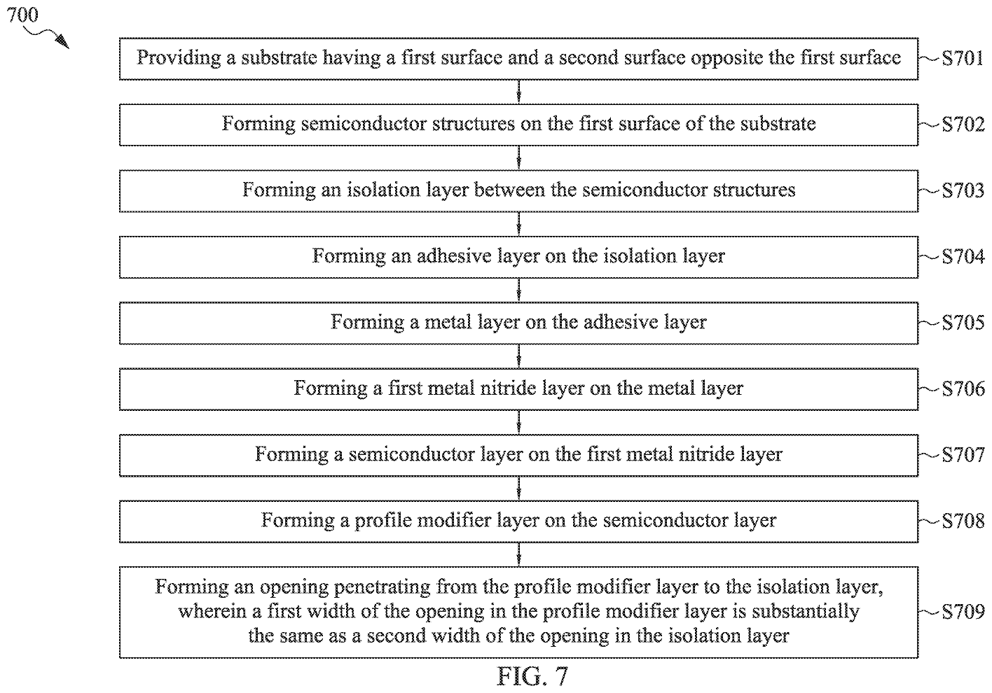

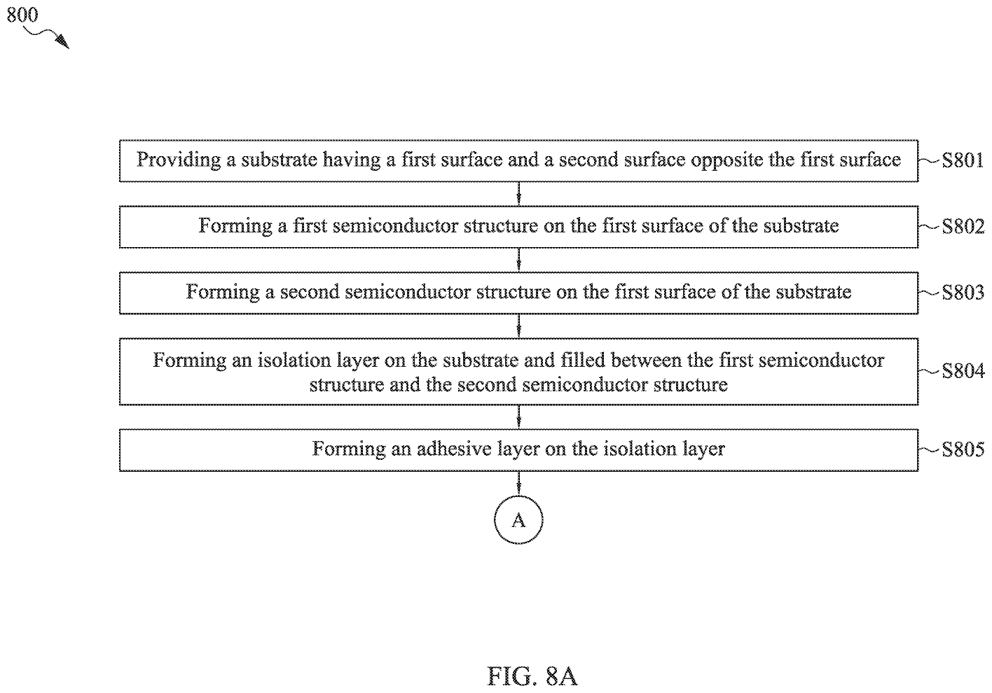

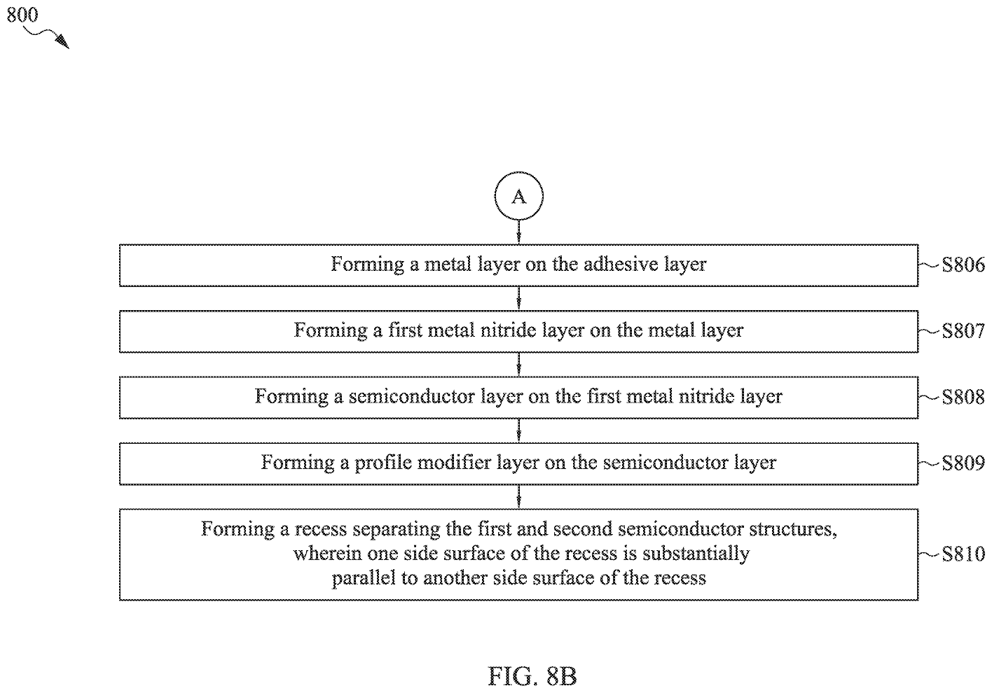

During the CMG process, the metal layer 104, the metal nitride layer 105, the semiconductor layer 106, and the protection 107a may be etched anisotropically. This may cause top corner profile rounding of the hard mask, and thus adversely impact the subsequent manufacture processes of the semiconductor structure. Details of the semiconductor structure without the protection layer 107b are illustrated in the paragraph regarding FIG. 5.

Referring to FIG. 3N, a CMG process is performed. The isolation layer 102, the adhesive layer 103, and the metal layer 104 are patterned. An opening 102r is formed. In some embodiments, the opening 102r is formed by patterning the isolation layer 102, the adhesive layer 103, and the metal layer 104 by lithography. The isolation layer 102, the adhesive layer 103, and the metal layer 104 are separated into two sections. Two side surfaces of the opening 102r are substantially aligned with two side surfaces of the opening 108r. The opening 102r has a width W2.

In some embodiments, the opening 102r is formed by dry etching. The width W1 of the opening 107r of the profile modifier layer 107 is substantially the same as the width W2 of the opening 102r of the isolation layer 102. After removing the patterned photoresist layer 108, the semiconductor structure 10 as shown in FIG. 1 is formed.

FIG. 3A, FIG. 3B, FIG. 3C, FIG. 3D, FIG. 3E, FIG. 3F, FIG. 3G, FIG. 3H, FIG. 4A, FIG. 4B, FIG. 4C, FIG. 4D, and FIG. 4E illustrate various stages of manufacturing a semiconductor device structure, in accordance with some embodiments of the present disclosure. FIG. 3A, FIG. 3B, FIG. 3C, FIG. 3D, FIG. 3E, FIG. 3F, FIG. 3G, and FIG. 3H are illustrated as noted.

As shown in FIG. 4A, a protection layer 207 is formed on the semiconductor layer 106. The protection layer 207 contacts the semiconductor layer 106. In some embodiments, the protection layer 207 may be formed by plasma enhanced chemical vapor deposition (PECVD). In some embodiments, the thickness of the protection layer 207 exceeds that of the semiconductor layer 106. In some embodiments, the thickness of the protection layer 207 exceeds that of the protection layer 107b in FIG. 3J.

As shown in FIG. 4B, a patterned photoresist layer 208 is formed on the protection layer 207. The patterned photoresist layer 208 contacts the protection layer 207. The patterned photoresist layer 208 includes two separated sections. The two sections are spaced apart by an opening 208r. In some embodiments, the opening 208r is substantially disposed in the center of the patterned photoresist layer 208. In some embodiments, the opening 208r is formed between the semiconductor structures 101b and 101c in a vertical orientation.

Referring to FIG. 4C, the protection layer 207 is patterned. An opening 207r is formed. In some embodiments, the opening 207r is formed by patterning the protection layer 207 by lithography. The protection layer 207 is separated into two sections. Two side surfaces of the opening 207r are substantially aligned with two side surfaces of the opening 208r. In some embodiments, the opening 207r is formed by dry etching. The opening 207r has a width W3.

Referring to FIG. 4D, the metal nitride layer 105 and the semiconductor layer 106 are patterned. An opening 205r is formed. Two side surfaces of the opening 205r are substantially aligned with two side surfaces of the opening 208r. In some embodiments, the opening 205r is formed by dry etching. In some embodiments, the opening 205r is formed by patterning the metal nitride layer 105 by lithography.

Referring to FIG. 4E, a CMG process is performed. The isolation layer 102, the adhesive layer 103, and the metal layer 104 are patterned. An opening 202r is formed. In some embodiments, the opening 202r is formed by patterning the isolation layer 102, the adhesive layer 103, and the metal layer 104 by lithography. The isolation layer 102, the adhesive layer 103, and the metal layer 104 are separated into two sections. Two side surfaces of the opening 202r are substantially aligned with two side surfaces of the opening 208r. The opening 202r has a width W4.

In some embodiments, the opening 202r is formed by dry etching. The width W3 of the opening 207r of the protection layer 207 is substantially the same as the width W4 of the opening 202r of the isolation layer 102. After removing the patterned photoresist layer 208, the semiconductor structure 20 as shown in FIG. 2 is formed.

FIG. 5 illustrates an exemplary cross-section of a semiconductor structure, in accordance with some comparative embodiments of the present disclosure. The difference between the semiconductor structure 50 in FIG. 5 and the semiconductor structure 10 in FIG. 1 is that the semiconductor structure 50 lacks the protection layer 107b, and the recess 50t is not substantially rectangular in cross section.

As shown in FIG. 5, an angle A5 between the surface 507u and a side surface 507s1 of a section 507a of the protection layer 507 is an obtuse angle. In some embodiments, the angle A5 exceeds 90°. In some embodiments, the angle A5 is less than 150°. An angle A6 between the surface 507u and a side surface 507s2 of a section 507b of the protection layer 507 is an obtuse angle. In some embodiments, the angle A6 exceeds 90°. In some embodiments, the angle A6 is less than 150°. In some embodiments, the angle A5 exceeds the angle A6. In some embodiments, the angle A5 is less than the angle A6. In some embodiments, the angle A5 is substantially the same as the angle A6. In some embodiments, the side surface 507s1 of the section 507a is non-parallel to the side surface 507s2 of the section 507b.

As shown in FIG. 5, a recess 50t is formed between the semiconductor structures 101b and 101c. The recess 50t includes a tapered profile in cross section. The recess 50t separates the semiconductor structures 101b and 101c. The recess 50t extends from a top surface 507u of the protection layer 507 to the surface 100a of the substrate 100. The recess 50t extends from the protection layer 507 to the isolation layer 102. The isolation layer 102, the adhesive layer 103, the metal layer 104, the metal nitride layer 105, the semiconductor layer 106, and the protection layer 507 are separated into two sections by the recess 50t. In some embodiments, the depth of the recess 50t is in a range of about 250 Å to about 12400 Å.

The recess 50t may include openings for separating the isolation layer 102, the adhesive layer 103, the metal layer 104, the first metal nitride layer 105, the semiconductor layer 106, and the protection layer 507. In some embodiments, an opening 502r separates the isolation layer 102 into two sections. An opening 507r separates the protection layer 507 into two sections. A width W5 of the opening 507r in the protection layer 507 exceeds a width W6 of the opening 502r in the isolation layer 102. The recess 50t separates the protection layer 507 by the width W5 and separates the isolation layer 102 by the width W6. In some embodiments, one side surface 50t1 of the recess 50t is substantially parallel to another side surface 50t2 of the recess 50t.

The thermal budge of a process may be defined as the temperature of the process times the duration of the process. Since the protection layer 207 of the semiconductor structure 20 is formed with a metal oxide material, rather than a metal nitride material, the process temperature of manufacturing the protection layer 207 in FIG. 2 may be lower than that of manufacturing the protection layer 507 in FIG. 5. Thus, the thermal budge of the layer deposition process of the semiconductor structure 20 can be lower than that of the semiconductor structure 50. The thermal budge of the layer deposition process of the semiconductor structure 20 can be even lower than that of the semiconductor structure 10.

FIG. 3A, FIG. 3B, FIG. 3C, FIG. 3D, FIG. 3E, FIG. 3F, FIG. 3G, FIG. 3H, FIG. 6A, FIG. 6B, FIG. 6C, FIG. 6D, and FIG. 6E illustrate various stages of manufacturing a semiconductor device structure, in accordance with some embodiments of the present disclosure. FIG. 3A, FIG. 3B, FIG. 3C, FIG. 3D, FIG. 3E, FIG. 3F, FIG. 3G, FIG. 3H and FIG. 3I are illustrated as noted.

As shown in FIG. 6A, a protection layer 507 is formed on the semiconductor layer 106. The protection layer 507 can also be referred to as a profile modifier layer. The protection layer 507 contacts the semiconductor layer 106. In some embodiments, the protection layer 507 may be formed by plasma enhanced chemical vapor deposition (PECVD). In some embodiments, the thickness of the protection layer 507 exceeds that of the semiconductor layer 106.

As shown in FIG. 6B, a patterned photoresist layer 508 is formed on the protection layer 507. The patterned photoresist layer 508 contacts the protection layer 507. The patterned photoresist layer 508 includes two separated sections. The two sections are spaced apart by an opening 508r. In some embodiments, the opening 508r is substantially disposed in the center of the patterned photoresist layer 508. In some embodiments, the opening 508r is formed between the semiconductor structures 101b and 101c along a vertical orientation.

Referring to FIG. 6C, the protection layer 507 is patterned. An opening 507r is formed. In some embodiments, the opening 507r is formed by patterning the protection layer 507 by lithography. The protection layer 507 is separated into two sections. Two side surfaces of the opening 507r are substantially aligned with two side surfaces of the opening 508r. In some embodiments, the opening 507r is formed by dry etching. The opening 507r has a width W5′.

Referring to FIG. 6D, the metal nitride layer 105 and the semiconductor layer 106 are patterned. An opening 505r is formed. In some embodiments, the opening 505r is formed by patterning the metal nitride layer 105 and the semiconductor layer 106 by lithography. The metal nitride layer 105 and the semiconductor layer 106 are separated into two sections. Two side surfaces of the opening 505r are substantially aligned with two side surfaces of the opening 508r. As shown in FIG. 6D, portions of the protection layer 507 are laterally and anisotropically etched.

Referring to FIG. 6E, a CMG process is performed. The isolation layer 102, the adhesive layer 103, and the metal layer 104 are patterned. An opening 502r is formed. In some embodiments, the opening 502r is formed by patterning the isolation layer 102, the adhesive layer 103, and the metal layer 104 by lithography. The isolation layer 102, the adhesive layer 103, and the metal layer 104 are separated into two sections. In some embodiments, the opening 502r is formed by dry etching. Two side surfaces of the opening 502r are substantially aligned with two side surfaces of the opening 508r. The opening 502r has a width W6. As shown in FIG. 6E, portions of the protection layer 507 are further laterally and anisotropically etched. Portions of the metal nitride layer 105 and the semiconductor layer 106 are laterally and anisotropically etched. Referring to FIG. 6E, the maximum distance between the two sections of the protection layer 507 is W5. In some embodiments, the width W5 exceeds the width W6.

After removing the patterned photoresist layer 508 from the semiconductor structure shown in FIG. 6E, the semiconductor structure 50 as shown in FIG. 5 is formed.

FIG. 7 is a flowchart illustrating a method for manufacturing a semiconductor device, in accordance with various aspects of the present disclosure.

The method 700 includes operation S701. In operation S701, a substrate having a first surface and a second surface opposite the first surface is provided. For example, the substrate 100 having a first surface 100a and a second surface 100b opposite the first surface 100a as shown in FIG. 1, is provided.

The method 700 includes operation S702. In operation S702, semiconductor structures are formed on the first surface of the substrate. For example, semiconductor structures 101a-101d are formed on the first surface 100a of the substrate 100, as shown in FIG. 1.

The method 700 includes operation S703. In operation S703, an isolation layer between the semiconductor structures is formed. For example, an isolation layer 102 between the semiconductor structures 101a-101d is formed, as shown in FIG. 1.

The method 700 includes operation S704. In operation S704, an adhesive layer is formed on the isolation layer. For example, an adhesive layer 103 is formed on the isolation layer 102, as shown in FIG. 1.

The method 700 includes operation S705. In operation S705, a metal layer is formed on the adhesive layer 103. For example, a metal layer 104 is formed on the adhesive layer 103, as shown in FIG. 1.

The method 700 includes operation S706. In operation S706, a first metal nitride layer is formed on the metal layer. For example, a first metal nitride layer 105 is formed on the metal layer 104, as shown in FIG. 1.

The method 700 includes operation S707. In operation S707, a semiconductor layer is formed on the first metal nitride layer. For example, a semiconductor layer 106 is formed on the first metal nitride layer 105, as shown in FIG. 1.

The method 700 includes operation S708. In operation S708, a profile modifier layer is formed on the semiconductor layer. For example, a profile modifier layer 107 is formed on the semiconductor layer 106, as shown in FIG. 1.

The method 700 includes operation S709. In operation S709, an opening penetrating from the profile modifier layer to the isolation layer is formed. For example, an opening 107r penetrating from the profile modifier layer 107 to the isolation layer 102 is formed, as shown in FIG. 1. A first width W1 of the opening 107r in the profile modifier layer 107 is substantially the same as a second width W2 of the opening in the isolation layer 102.

The method 700 is merely an example, and is not intended to limit the present disclosure beyond what is explicitly recited in the claims. Additional operations can be provided before, during, or after each operation of the method 700, and some operations described can be replaced, eliminated, or reordered for additional embodiments of the method. In some embodiments, the method 700 can include further operations not depicted in FIG. 7.

FIGS. 8A and 8B are flowcharts illustrating a method for manufacturing a semiconductor device, in accordance with various aspects of the present disclosure.

The method 800 includes operation S801. In operation S801, a substrate having a first surface and a second surface opposite the first surface is provided. For example, the substrate 100 having a first surface 100a and a second surface 100b opposite the first surface 100a as shown in FIG. 1, is provided.

The method 800 includes operation S802. In operation S802, a first semiconductor structure is formed on the first surface of the substrate. For example, a first semiconductor structure 101b is formed on the first surface 100a of the substrate 100, as shown in FIG. 1.

The method 800 includes operation S803. In operation S803, a second semiconductor structure is formed on the first surface of the substrate. For example, a second semiconductor structure 101c is formed on the first surface 100a of the substrate 100, as shown in FIG. 1.

The method 800 includes operation S804. In operation S804, an isolation layer is formed on the substrate and filled between the first semiconductor structure and the second semiconductor structure. For example, an isolation layer 102 is formed on the substrate 100 and filled between the first semiconductor structure 101b and the second semiconductor structure 101c, as shown in FIG. 1.

The method 800 includes operation S805. In operation S805, an adhesive layer is formed on the isolation layer. For example, an adhesive layer 103 is formed on the isolation layer 102, as shown in FIG. 1.

The method 800 includes operation S806. In operation S806, a metal layer is formed on the adhesive layer. For example, a metal layer 104 is formed on the adhesive layer 103, as shown in FIG. 1.

The method 800 includes operation S807. In operation S807, a first metal nitride layer is formed on the metal layer. For example, a first metal nitride layer 105 is formed on the metal layer 104, as shown in FIG. 1.

The method 800 includes operation S808. In operation S808, a semiconductor layer is formed on the first metal nitride layer. For example, a semiconductor layer 106 is formed on the first metal nitride layer 105, as shown in FIG. 1.

The method 800 includes operation S809. In operation S809, a profile modifier layer is formed on the semiconductor layer. For example, a profile modifier layer 107 is formed on the semiconductor layer 106, as shown in FIG. 1.

The method 800 includes operation S810. In operation S810, a recess separating the first and second semiconductor structures is formed. For example, a recess 10t separating the first and second semiconductor structures 101b and 101c is formed, as shown in FIG. 1. One side surface 10t of the recess 10t is substantially parallel to another side surface 10t2 of the recess 10t.

The method 800 is merely an example, and is not intended to limit the present disclosure beyond what is explicitly recited in the claims. Additional operations can be provided before, during, or after each operation of the method 700, and some operations described can be replaced, eliminated, or reordered for additional embodiments of the method. In some embodiments, the method 800 can include further operations not depicted in FIGS. 8A and 8B.

Some embodiments of the present disclosure provide a semiconductor structure. The semiconductor structure includes a substrate, semiconductor structures, an isolation layer, an adhesive layer, a metal layer, a first metal nitride layer, a semiconductor layer, a profile modifier layer, and a disconnection structure. The substrate has a first surface and a second surface opposite the first surface. The semiconductor structures are disposed on the first surface of the substrate. The isolation layer is disposed between the semiconductor structures. The adhesive layer is disposed on the isolation layer. The metal layer is disposed on the adhesive layer. The first metal nitride layer is disposed on the metal layer. The semiconductor layer is disposed on the first metal nitride layer. The profile modifier layer is disposed on the semiconductor layer. The disconnection structure is disposed between two of the semiconductor structures and extending from the profile modifier layer to the isolation layer. A first width of the disconnection structure in the profile modifier layer is substantially the same as a second width of the disconnection structure in the isolation layer.

Some embodiments of the present disclosure provide a method of manufacturing a semiconductor structure. The method comprises providing a substrate having a first surface and a second surface opposite the first surface, forming semiconductor structures on the first surface of the substrate, forming an isolation layer between the semiconductor structures, forming an adhesive layer on the isolation layer, forming a metal layer on the adhesive layer, forming a first metal nitride layer on the metal layer, forming a semiconductor layer on the first metal nitride layer, forming a profile modifier layer on the semiconductor layer, and forming an opening penetrating from the profile modifier layer to the isolation layer, wherein a first width of the opening in the profile modifier layer is substantially the same as a second width of the opening in the isolation layer.

Some embodiments of the present disclosure provide a method of manufacturing a semiconductor structure. The method comprises providing a substrate having a first surface and a second surface opposite the first surface, forming a first semiconductor structure on the first surface of the substrate, forming a second semiconductor structure on the first surface of the substrate, forming an isolation layer on the substrate and filled between the first semiconductor structure and the second semiconductor structure, forming an adhesive layer on the isolation layer, forming a metal layer on the adhesive layer, forming a first metal nitride layer on the metal layer, forming a semiconductor layer on the first metal nitride layer, forming a profile modifier layer on the semiconductor layer, and forming a recess separating the first and second semiconductor structures, wherein one side surface of the recess is substantially parallel to another side surface of the recess.

The foregoing outlines structures of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate having a first surface and a second surface opposite the first surface;
semiconductor structures disposed on the first surface of the substrate;
an isolation layer disposed between the semiconductor structures;
an adhesive layer disposed on the isolation layer;
a metal layer disposed on the adhesive layer;
a first metal nitride layer disposed on the metal layer;
a semiconductor layer disposed on the first metal nitride layer;
a profile modifier layer disposed on the semiconductor layer; and
a disconnection structure disposed between two of the semiconductor structures and extending from the profile modifier layer to the isolation layer, wherein
a first width of the disconnection structure in the profile modifier layer is substantially the same as a second width of the disconnection structure in the isolation layer.

2. The semiconductor device of claim 1, wherein the profile modifier layer comprises a first protection layer and a second protection layer disposed on the semiconductor layer.

3. The semiconductor device of claim 2, wherein the first protection layer comprises one of SiCN, SiN, SiCON, SiOC, or SiON.

4. The semiconductor device of claim 2, wherein the second protection layer comprises a metal oxide layer or a metal nitride layer.

5. The semiconductor device of claim 4, wherein metal material of the metal oxide layer or the metal nitride layer is selected from Zr, Hf, Al, or Y.

6. The semiconductor device of claim 2, wherein the second protection layer has a greater etching resistivity to CMG process than that of the first protection layer.

7. A method for manufacturing a semiconductor device, comprising:
providing a substrate having a first surface and a second surface opposite the first surface;
forming semiconductor structures on the first surface of the substrate;
forming an isolation layer between the semiconductor structures;
forming an adhesive layer on the isolation layer;
forming a metal layer on the adhesive layer;
forming a first metal nitride layer on the metal layer;
forming a semiconductor layer on the first metal nitride layer;
forming a profile modifier layer on the semiconductor layer; and
forming an opening penetrating from the profile modifier layer to the isolation layer, wherein a first width of the opening in the profile modifier layer is substantially the same as a second width of the opening in the isolation layer.

8. The method of claim 7, wherein the profile modifier layer comprises a first protection layer and a second protection layer disposed on the semiconductor layer.

9. The method of claim 8, wherein the first protection layer is formed by plasma enhanced chemical vapor deposition (PECVD).

10. The method of claim 7, wherein the opening of the profile modifier layer is formed by dry etching.

11. The method of claim 7, wherein an angle between a horizontal surface and a side surface of the profile modifier layer exceeds 80°.

12. The method of claim 7, wherein an angle between a horizontal surface and a side surface of the profile modifier layer is less than 100°.

13. The method of claim 7, wherein the opening of the isolation layer is formed by dry etching.

14. The method of claim 7, wherein forming the opening of the profile modifier layer comprising patterning the profile modifier layer by lithography.

15. The method of claim 7, wherein the adhesive layer comprises two layers of different materials.

16. A method for manufacturing a semiconductor device, comprising:
providing a substrate having a first surface and a second surface opposite the first surface;
forming a first semiconductor structure on the first surface of the substrate;
forming a second semiconductor structure on the first surface of the substrate;
forming an isolation layer on the substrate and filled between the first semiconductor structure and the second semiconductor structure;
forming an adhesive layer on the isolation layer;
forming a metal layer on the adhesive layer;
forming a first metal nitride layer on the metal layer;
forming a semiconductor layer on the first metal nitride layer;
forming a profile modifier layer on the semiconductor layer; and
forming a recess separating the first and second semiconductor structures, wherein one side surface of the recess is substantially parallel to another side surface of the recess.

17. The method of claim 16, wherein the recess extends from a top surface of the profile modifier layer to a top surface of the substrate.

18. The method of claim 16, wherein the recess separates the profile modifier layer by a first width and separates the isolation layer by a second width substantially identical to the first width.

19. The method of claim 16, wherein the recess separates the profile modifier layer into two sections.

20. The method of claim 16, wherein the recess is substantially rectangular.
